(19) United States
(12) Patent Application Publication
(10) Pub. No.: US 2009/0098673 A1
(43) Pub. Date: Apr. 16, 2009

(54) THIN FILM TRANSISTOR ARRAY PANEL AND METHOD FOR MANUFACTURING THE SAME

(75) Inventors: Sung-Hoon Yang, Seoul (KR); Kunal Satyabhushan Girotra, Gyeonggi-do (KR); Byoung-June Kim, Gyeonggi-do (KR)

Correspondence Address: MACPHERSON KWOK CHEN & HEID LLP, 2033 GATEWAY PLACE, SUITE 400, SAN JOSE, CA, 95110, US

(73) Assignee: Samsung Electonics Co. Ltd., Suwon-si (KR)

(21) Appl. No.: 12/334,241

(22) Filed: Dec. 12, 2008

Related U.S. Application Data
(62) Division of application No. 11/262,163, filed on Oct. 27, 2005.

(30) Foreign Application Priority Data
Dec. 8, 2004 (KR) 2004-103020

(51) Int. Cl. H01L 21/77

(52) U.S. Cl. 438/29; 257/E21.535

(57) ABSTRACT

A TFT array panel-including a substrate, a gate line having a gate electrode, a gate insulating layer formed on the gate line, a data line having a source electrode and a drain electrode spaced apart from the source electrode, a passivation layer formed on the data line and the drain electrode, and a pixel electrode connected to the drain electrode is provided. The TFT array panel further includes a protection layer including Si under at least one of the gate insulating layer and the passivation layer to enhance reliability.

### CROSS-REFERENCE TO RELATED APPLICATION

This application is a divisional of U.S. patent application Ser. No. 11/262,163, filed Nov. 28, 2005, which claims priority to Korean Patent Application No. 2004-103020, filed on Dec. 8, 2004, the disclosure of which is hereby incorporated herein by reference in its entirety for all purposes.

### BACKGROUND

1. Field of the Invention

The present invention relates generally to a thin film transistor (TFT) array panel for liquid crystal displays (LCDs) or active matrix organic light emitting displays (AM-OLEDs), and to methods of fabricating the same, and in particular to a TFT array panel having low resistivity wire lines and to methods of fabricating the same.

2. Description of Related Art

Liquid crystal displays (LCDs) are one of the most widely used types of flat panel displays. An LCD includes two panels provided with field-generating electrodes and a liquid crystal (LC) layer interposed there between. The LCD displays images by applying voltages to the field-generating electrodes to generate an electric field in the LC layer, which determines orientations of LC molecules in the LC layer to adjust polarization of incident light.

One panel has pixel electrodes arranged in a matrix type. The other panel has a common electrode which covers the whole surface of the other panel. LCD displays images by applying a voltage to each pixel electrode. Each pixel electrode is connected to a TFT which controls the voltage for each pixel electrode. Each TFT is controlled by a voltage on a gate line and is connected to a data line (sometimes called a “data bus line”) which carries a data signal. The TFT is a switching device for controlling a graphic signal supplied to each pixel electrode. The TFT is used as a switch device for LCDs and for AM-OLED.

Nowadays, as the display size becomes larger, the gate lines and the data bus lines connected to the TFT in the display become longer. An increase in the length of a wire line increases the line's resistance. Increased resistance increases signal delay.

In order to reduce signal delay, the gate bus lines and data bus lines need to be formed of materials having low resistivity.

Copper (Cu) is one material having low resistivity. Cu can be used for the wire line of large displays with reduced signal delays. However, Cu has a weak resistance to chemicals, such as gases, for example NH3(g), to which Cu is exposed during fabrication. Also, Cu is hard to adhere to other layers. Thus, Cu applied to displays may result in displays having degraded reliability.

### SUMMARY

The present invention provides a TFT array panel with fewer defects generated during a manufacturing process thereof.

The present invention also provides a method for manufacturing the above TFT array panel.

In an exemplary TFT array panel according to the present invention, the TFT array panel includes a substrate, a gate line formed on the substrate, a gate insulating layer formed on the gate line, a data line having a source electrode and a drain electrode spaced apart from the source electrode, a passivation layer formed on the data line and the drain electrode, a pixel electrode connected to the drain electrode, and a protection layer including Si under at least one of the gate insulating layer and the passivation layer.

The protection layer can be formed of SiO2 or silicide.

In an exemplary method of manufacturing a TFT array panel according to this present invention, the method includes forming a gate line on a substrate, forming a gate insulating layer on the gate line, forming a semiconductor layer on the gate insulating layer, forming a data line having a source electrode and a drain electrode spaced apart from the source electrode on the semiconductor layer and the gate insulating layer, forming a pixel electrode connected to the drain electrode, forming a passivation layer, and forming a protection layer before at least one of forming the gate insulating layer and the passivation layer.

In one embodiment, the protection layer is formed by forming an amorphous silicon layer and annealing the amorphous silicon layer before forming the gate insulating layer or the passivation layer. In other embodiments, the protection layer is formed of SiO₂ or silicide.

### BRIEF DESCRIPTION OF THE DRAWINGS

The features of the present invention will become more apparent to those of ordinary skill in the art by describing in detail exemplary embodiments thereof with reference to the attached drawings, in which:

FIG. 1 is a plan view of a TFT array panel for a LCD according to an embodiment of the present invention;

FIG. 2 is a cross-sectional view taken along the line II-II′ of the TFT array panel of FIG. 1;

FIG. 3A is a plan view of TFT array panel in one step according to an embodiment of the present invention;

FIG. 3B is a cross sectional view taken along the line IIIB-IIIB′ of the TFT array panel shown in FIG. 3A;

FIGS. 4 and 5 are cross sectional views showing the fabrication steps following the step of FIGS. 3A and 3B;

FIG. 6A is a plan view showing another step of fabricating a TFT array panel according to an embodiment of the present invention;

FIG. 6B is a cross sectional view taken along the line VIB-VIB′ of the TFT array panel of FIG. 6A;

FIG. 7A is a plan view showing another step of fabricating a TFT array panel according to an embodiment of the present invention;

FIG. 7B is a cross sectional view taken along the line VIIB-VIIB′ of the TFT array panel of FIG. 7A;

FIG. 8 is a cross sectional view taken along the line VIIB-VIIB′ showing the structure following the process steps shown in FIG. 7A;

FIG. 9A is a plan view showing another step in the fabrication of a TFT array panel according to an embodiment of the present invention;

FIG. 9B is a cross sectional view taken along the line IXB-IXB′ of the TFT array panel of FIG. 9A;

FIG. 10 is a plan view of a TFT array panel for a LCD according to another embodiment of the present invention;

FIG. 11 is a cross sectional view taken along the line XI-XI′ of the TFT array panel of FIG. 10;

FIG. 12A is a plan view showing a step in the fabrication of a TFT array panel according to another embodiment of the present invention;

FIG. 12B is a cross sectional view taken along the line XIIB-XIIB′ of the TFT array panel of FIG. 12A;

FIGS. 13 to 17 are cross sectional views showing a TFT structure at different steps in the fabrication process following the structure of FIG. 12B;

FIG. 18A is a plan view showing a step of fabricating a TFT array panel according to another embodiment of the present invention;

FIG. 18B is a cross sectional view taken along the line XVIIIB-XVIIIB′ of the TFT array panel of FIG. 18A;

FIG. 19 is a cross sectional view showing the TFT structure of FIG. 18B with protection layer 803 formed thereon;

FIG. 20A is a plan view showing a step of fabricating TFT array panel at an intermediate stage in fabrication according to another embodiment of the present invention; and

FIG. 20B is a cross sectional view taken along the line XXB-XXB′ of the TFT array panel of FIG. 20A.

Use of the same reference symbols in different figures indicates similar or identical items.

### DETAILED DESCRIPTION

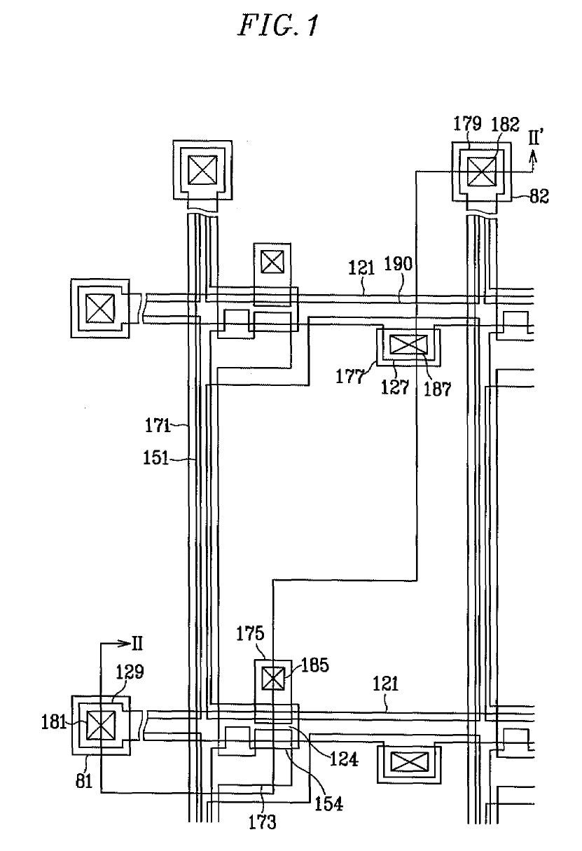

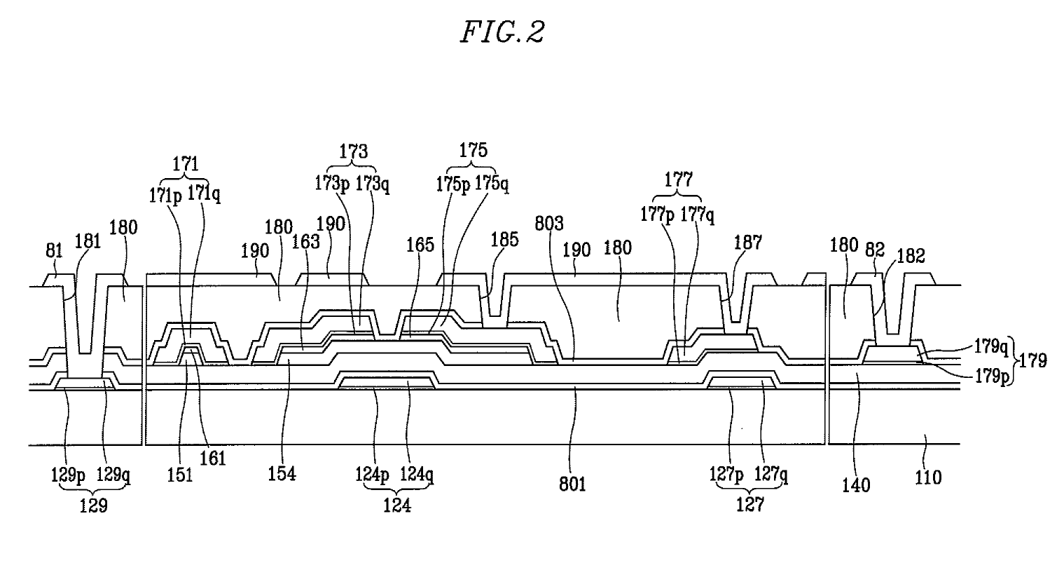

FIG. 1 shows a plan view of a TFT array panel according to an embodiment of the present invention, and FIG. 2 shows a cross-section taken along the line II-II′ of the structure of FIG. 1.

Referring to FIGS. 1 and 2, a plurality of gate lines 121 transmitting gate signals are formed on an insulating substrate 110. Gate lines 121 extend in a horizontal direction, and a portion of each gate line 121 forms a gate electrode 124. Another portion of each gate line 121 protrudes downward to form an expansion 127.

Gate line 121 is formed of a conductive material (i.e. copper layer) 124q, 127q and 129q including copper or a copper alloy, and a lower conductive layer 124p, 127p, and 129p of a material (such as molybdenum) selected to improve adhesion of the copper layer 124q, 127q, and 129q with the insulating substrate 110. The lower conductive layer 124p, 127p, and 129p can be made of not only molybdenum (Mo), but also chrome (Cr), titanium (Ti), tantalum (Ta), alloys thereof, nitrides thereof, or any combinations thereof.

The lower conductive layer 124p, 127p, and 129p prevents layer 124q, 127q, and 129q from lifting or peeling.

Layer 124q, 127q, and 129q, and lower conductive layer 124p, 127p, and, 129p may have tapered lateral sides having an inclination angle in the range of about 30 to 80 degrees, relative to the surface of the first substrate 110. These tapered lateral sides ensure that subsequent layers to be deposited will conform, without a break, to the underlying structure.

A protection layer 801 is formed on the gate lines 121 and the substrate 110. Protection layer 801 prevents the layer 124q, 127q, and 129q forming the gate lines 121 from corrosion and oxidation.

Protection layer 801 includes silicon(Si), and can be made of silicon oxide (SiO₂), silicon oxynitride (SiON), or silicide.

The thickness of protection layer 801 is about 30 Å to 300 Å to adequately protect underlying copper layer and to provide part of the dielectric for the storage capacitor associated with the array panel.

A gate insulating layer 140 formed of silicon nitride (SiNx) is formed over the protection layer 801.

Conventionally, gate insulating layer 140 including SiNx can be formed by passing silane (SiH₄), nitrogen (N₂) and ammonium (NH₃) gases at the same time over the substrate 110 having the gate lines 121. Without the presence of protection layer 801, NH3 gas corrodes metal. Accordingly, when the layer 124q, 127q, and 129q includes copper and is exposed to NH3 gas, layer 124q, 127q, and 129q oxidizes and corrodes. Oxidation and corrosion cause the resistance of the copper layer 124q, 127q, and 129q to increase, and the adhesion of copper layer 124q, 127q, and 129q with the gate insulating layer 140 to decrease. The decrease of the adhesion allows the gate insulating layer 140 to separate from the copper layer 124q, 127q, and 129q (i.e. layer 140 lift from layer 124q, 127q, and 129q).

The protection layer 801 between the copper layer 124q, 127q, and 129q and the gate insulating layer 140 solves these problems.

A plurality of semiconductor strips 151 made of hydrogenated amorphous silicon is formed over the gate insulating layer 140. Each semiconductor strip 151 extends in a longitudinal direction, a plurality of projections 154 branch out toward the gate electrode 124 from each semiconductor strip 151. The projections 154 covers a portion of the gate line 121 and the channel regions of the to-be-formed TFT will be formed in these projections 154.

A plurality of ohmic contact strips 161 having ohmic contact protrusions 163 and ohmic contact islands 165 made of silicide or n+ hydrogenated amorphous silicon highly doped with n type impurity are formed on the semiconductor strips 151. Ohmic contact layers 163 and 165 are formed apart from each other and disposed on the semiconductor projections 154. The lateral sides of the semiconductor layers 151 and 154, and the ohmic contact layers 161, 163, and 165 are inclined at angles in the range about 30 to 80 degrees relative to the surface of the substrate 110.

A plurality of data lines 171, a plurality of drain electrodes 175, and a plurality of storage capacitor conductors 177 are formed on the ohmic contact layer 161, 163, and 165 and the gate insulating layer 140.

The data lines 171 are configured to carry data signals and extend in the substantially longitudinal direction intersecting the gate lines 121. Each data line 171 has an end portion 179 having a relatively large area for contact with other layers or external devices. The data lines 171 may include a plurality of branches that protrude toward the drain electrodes 175. These branches form source electrodes 173. Each pair of the source electrodes 173 and the drain electrodes 175 is located at least in part on corresponding ohmic contact layers 163 and 165, and separated from and opposite each other with respect to the corresponding gate electrodes 124.

The data lines 171 including the source electrodes 173, the drain electrodes 175 and the storage capacitor conductors 177 can be formed of double layers. Upper layers 171q, 173q, 175q, 177q, and 179q include Cu. Lower layers 171p, 173p, 175p, 177p, and 179p include Mo, Cr, Ti, Ta, alloys thereof, nitrides thereof, or any combination thereof to prevent Cu from entering into the semiconductor layers 151 and 154, and the ohmic contact layers 161, 163, and 164.

In another embodiment, the data lines 171 and the drain electrodes 175 can be formed of Cu single layer or multi-layer not less than triple layer.

Like the gate lines 121, the data lines 171, the drain electrodes 175 and the storage capacitor conductor 177 may have tapered lateral sides having an inclination angle in the range of about 30 to 80 degrees, relative to the surface of the first substrate 110.

The gate electrode 124, the source electrode 173, the drain electrode 175 and the projection 154 of the semiconductor strip 151 together forms a TFT. A TFT channel (not shown) is formed on the projection 154 between the source electrode 173 and the drain electrode 175. The storage capacitor conductor 177 overlaps the expansion 127 of the gate line 121.

The ohmic contact islands 163 and 165 are disposed between the projection 154 of the semiconductor layer, and the source electrode 173 and the drain electrode 175 respectively to decrease the contact resistance between the projection 154, on the one hand and the source electrode 173 and the drain electrode 175 on the other hand. The width of most portions of the semiconductor strip 151 is narrower than the width of the data line 171. However, the width of the semiconductor strip 151 expands at the point of intersecting the gate line 121 to prevent the short of the data line 171 and the gate line 121.

A protection layer 803 is formed on the data line 171, the drain electrode 175, the storage capacitor conductor 177, the ending portion 179 and the exposed semiconductor layer 151.

The protection layer 803 prevents the copper layer 171q, 173q, 175q, 177q, and 179q from oxidation and corrosion during the following process.

The protection layer 803 is formed of material including silicon (Si), such as silicon oxide (SiO₂), silicon oxynitride (SiON), or silicide.

The thickness of the protection layer 803 is about 30 to 300 Å.

A passivation layer 180 made of silicon nitride (SiNx) is formed on the protection layer 803.

Conventionally, the passivation layer 180 including SiNx can be formed by providing silane (SiH₄), nitrogen (N₂) and ammonium (NH₃) gases at the same time. NH3 gas has a characteristic of corroding metal. Accordingly, when the copper layers 171q, 173q, 175q, 177q, and 179q are exposed to NH3 gas, copper layers 171q, 173q, 175q, 177q, and 179q oxidize and corrode. Oxidation and corrosion increase the resistance of the copper layers 171q, 173q, 175q, 177q, and 179q, and decrease the adhesion of the copper layers 171q, 173q, 175q, 177q, and 179q to different layers. The decrease of the adhesion allows the passivation layer 180 to separate.

The protection layer 803 between the copper layer 171q, 173q, 175q, 177q, and 179q and the passivation layer 180 solves these problems.

The passivation layer 180 includes a plurality of contact holes such as 181, 185, 187, and 182 to expose the end portion 129 of the gate line 121, a portion of the drain electrode 175, a portion of the storage capacitor conductor 177, and the end portion 129 of the data line 171 respectively.

A plurality of pixel electrodes 190 made of indium tin oxide (ITO) or indium zinc oxide (IZO), and contact assistants 81 and 82 is formed on the passivation layer 180.

The pixel electrode 190 is connected electrically to the drain electrode 175 through the contact hole 185 to receive a data voltage. Also, the pixel electrode 190 is connected to the storage capacitor conductor 177 through the contact hole 187 to transmit the data voltage.

In a LCD, the pixel electrode 190 provided with the data voltage and the other panel having a common electrode provided with a common voltage (not shown) generate an electric field in a LC layer (not shown) disposed between the pixel electrode 190 and the common electrode to orient LC molecules.

In view of electrical circuits (not shown), the pixel electrode 190 and the common electrode (not shown) forms a LC capacitor with a liquid crystal dielectric for storing electrical charges. The pixel electrode 190 and a gate line 121 of the neighboring pixel (i.e. a previous gate line) overlap to form a storage capacitor. The storage capacitor is formed in parallel to the LC capacitor to enhance the capability of storing electrical charges.

The expansion 127 of the gate line 121 increases the overlapping area with the pixel electrode, and the storage capacitor conductor 177 under the passivation 180 reduces the distance between the pixel electrode 190 and the previous gate line 121. This results in increasing the capacitance of the storage capacitor.

The contact assistants 81 and 82 are connected to the end portions 129 and 179 of the gate line 121 and the data line 171 through the contact holes 181 and 182 respectively. The contact assistants 81 and 82 protect the end portions 129 and 179 of the gate line 121 and the data line 171 and enhance adhesion of the end portions 129 and 179 with external devices. The contact assistants 82 are optional elements.

Hereinafter, a method for fabricating the TFT array panel of FIGS. 1 and 2 will be described in detail referring to FIGS. 3a to 9b, and FIGS. 1 and 2.

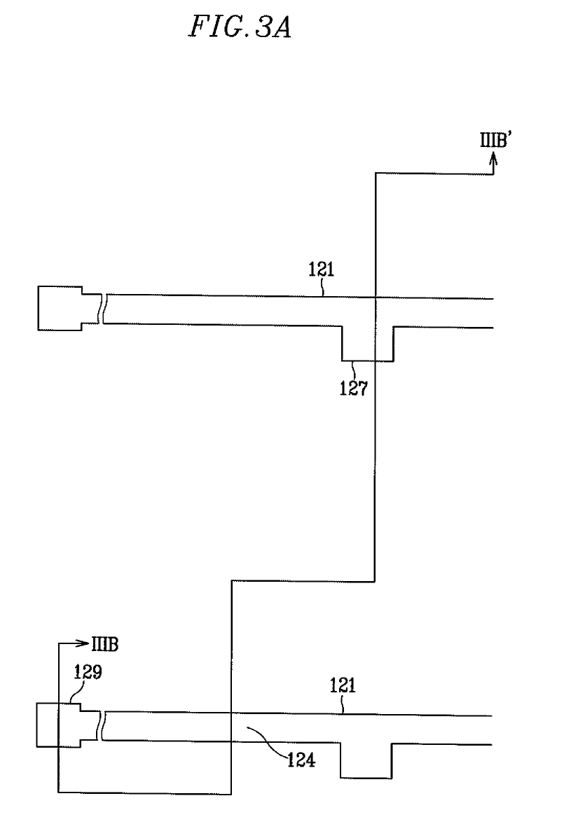

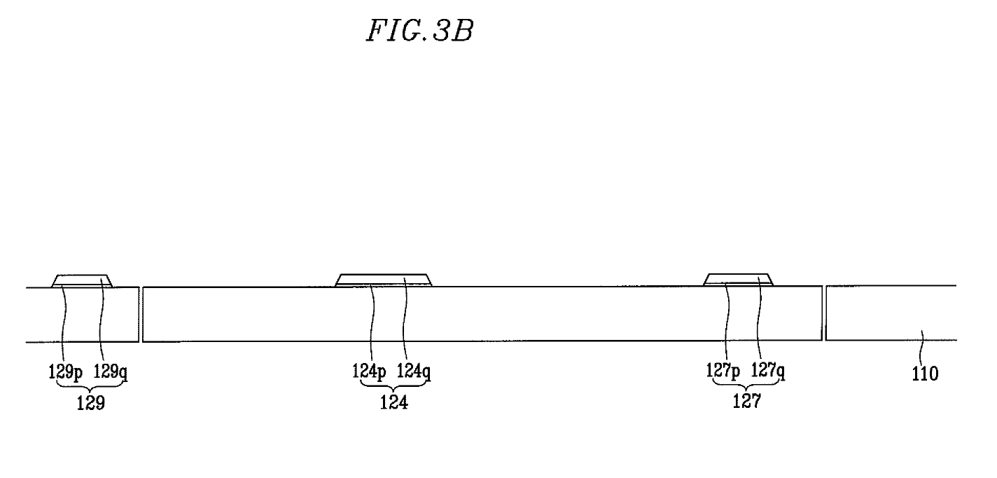

As shown in FIGS. 3A and 3B, a lower layer including Mo, Cr, Ti, Ta, alloys thereof, or nitrides thereof and a upper layer including Cu or Cu alloy (i.e Cu layer) are formed on a substrate 110 by co-sputtering.

In one embodiment, both a Cu target and a Mo target are located in a co-sputtering chamber. In the beginning, electric power is applied to only the Mo target so that the lower Mo layer 124p, 127p, and 129p is formed on the substrate 110. N2 gas can be provided to form molybdenum nitride during the Mo sputtering. In this case, molybdenum nitride formed between the lower layer and the to-be-formed Cu layer 124q, 127q, and 129q prevents Cu from diffusing into and through the lower layer 124p, 127p, and 129p. The thickness of the lower layer 124p, 127p, and 129p is about 30 Å to 300 Å.

After the electric power applied to the Mo target is turned off, electric power is applied to the Cu target to form Cu layer 124q, 127q, and 129q. The thickness of Cu layer 124q, 127q and 129q is about 1000 to 3000 Å.

The Mo layer under the Cu layer increases the adhesion of the Cu layer with the substrate 110 to prevent the Cu layer from peeling or lifting, and prevents oxidized Cu from diffusing into the substrate 110.

The double layer formed of the lower layer 124p, 127p, and 129p and the Cu layer 124q, 127q, and 129q is patterned to form the gate lines 121 including the gate electrodes 124, the expansions 127 and the end portions 129.

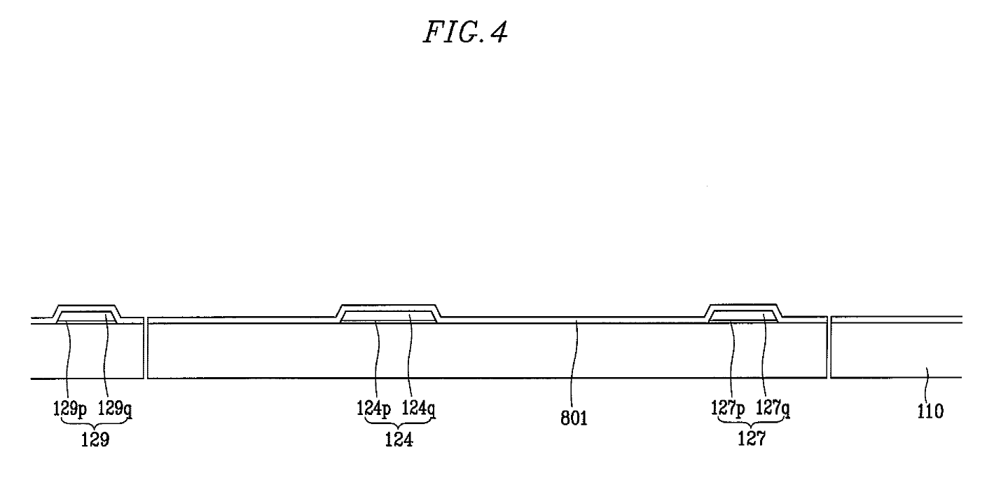

Referring to FIG. 4, a protection layer 801 is formed on the gate lines 121.

The protection layer 801 is formed of a material including Si, such as SiO₂, SiON, or amorphous Si by a plasma enhanced chemical vapor deposition (PECVD).

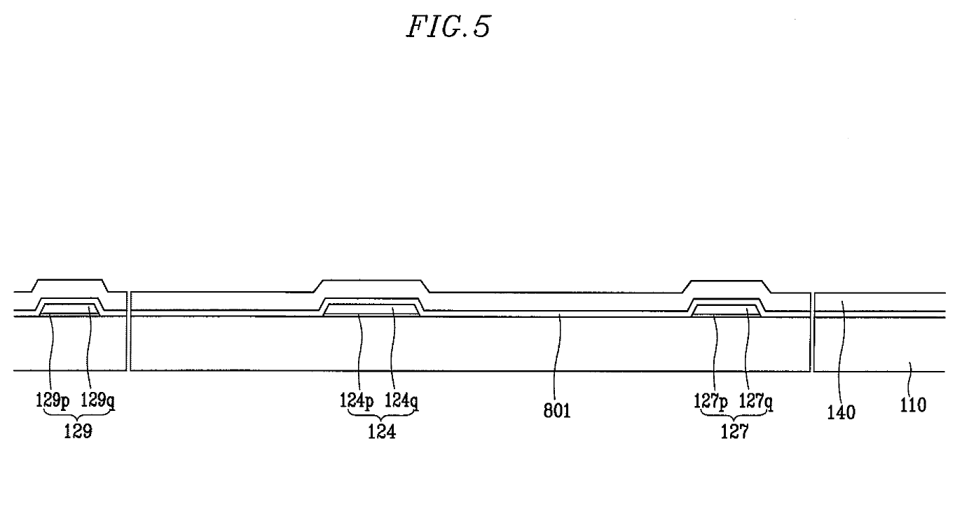

SiO₂ can be formed by providing SiH₄ and N₂O to the gate lines 121 by PECVD. At the same time, N₂ gas can be added to form SiON. The protection layer 801 formed of SiON may include more N₂ concentration in the upper portion of the protection layer 801 than in the lower portion, and may be formed of only nitride in the portion adjacent the gate insulating layer 140 (FIG. 5).

In another embodiment, amorphous silicon is formed on the gate lines 121 by PECVD, and then amorphous silicon is annealed at about 400° C. to 800° C. by a rapid thermal annealing (RTA) to react amorphous silicon with copper of the gate lines 121 to form copper silicide. Copper silicide can be formed at the interface of the gate lines 121 and the amorphous silicon by controlling the reaction condition.

The protection layer 801 protects the copper layer 124q, 127q, and 129q during the following process for forming a gate insulating layer 140. The thickness of the protection layer 801 is about 30 Å to 300 Å.

Referring to FIG. 5, the gate insulating layer 140 including SiNx is formed on protection layer 801 at a temperature typically in the range of about 250° C. to 500° C. The thickness of the gate insulating layer 140 is about 2,000 Å to 5,000 Å.

Conventionally, gate insulating layer 140 including SiNx can be formed by passing silane (SiH₄), nitrogen (N₂) and ammonium (NH₃) gases at the same time over the substrate 110 having the gate lines 121. NH₃ corrodes many metals.

Accordingly, when the copper layer 124q, 127q, and 129q is exposed to NH3 gas, copper layer 124q, 127q, and 129q oxidizes and corrodes. Oxidation and corrosion cause the resistance of the copper layer 124q, 127q, and 129q to increase, and decreases the adhesion of the copper layer 124q, 127q, and 129q to the gate insulating layer 140. The decrease of the adhesion allows the copper layer 124q, 127q, and 129q to separate from the gate insulating layer 140.

The protection layer 801 between the copper layer 124q, 127q, and 129q and the gate insulating layer 140 solves these problems.

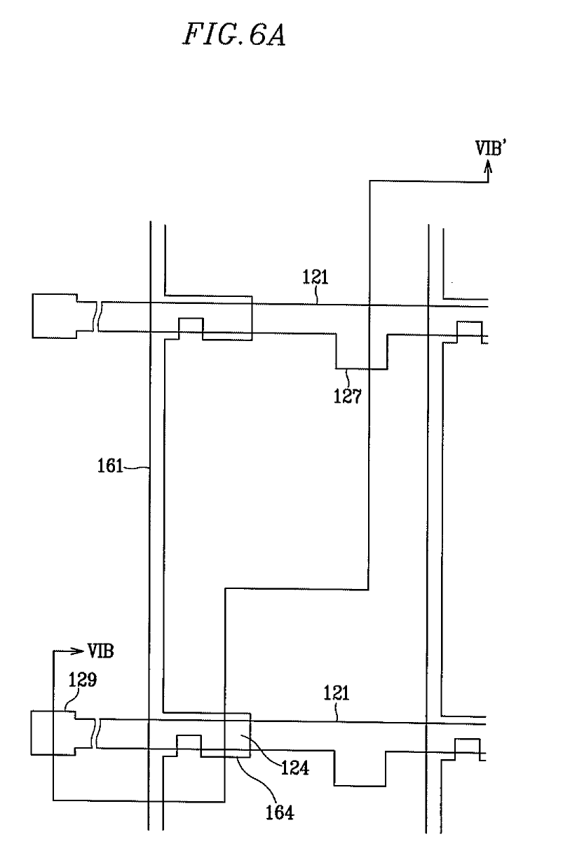

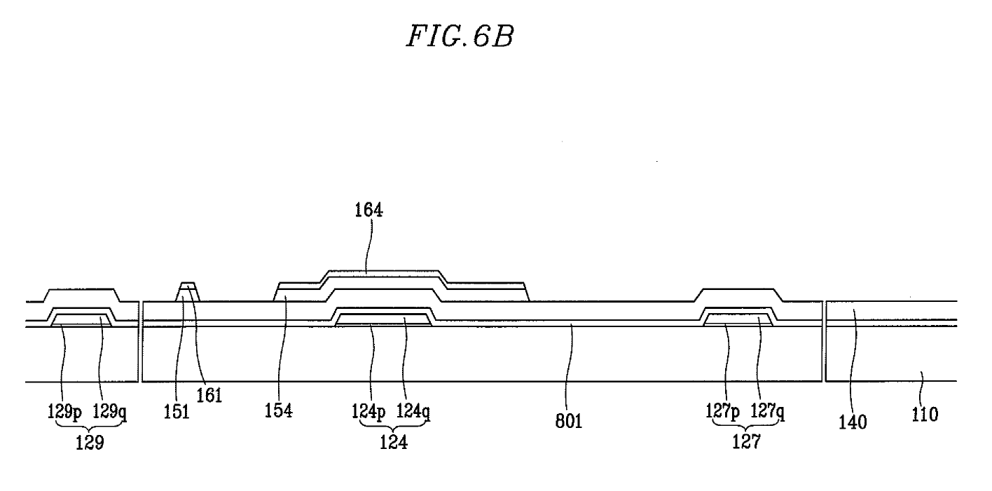

Referring to FIGS. 6A and 6B, intrinsic amorphous silicon, such as hydrogenated amorphous silicon (a-Si:H) and extrinsic amorphous silicon doped with impurities are deposited and are patterned to form semiconductor strips 151 including projections 154 and doped amorphous silicon layer 161 including protrusions 164.

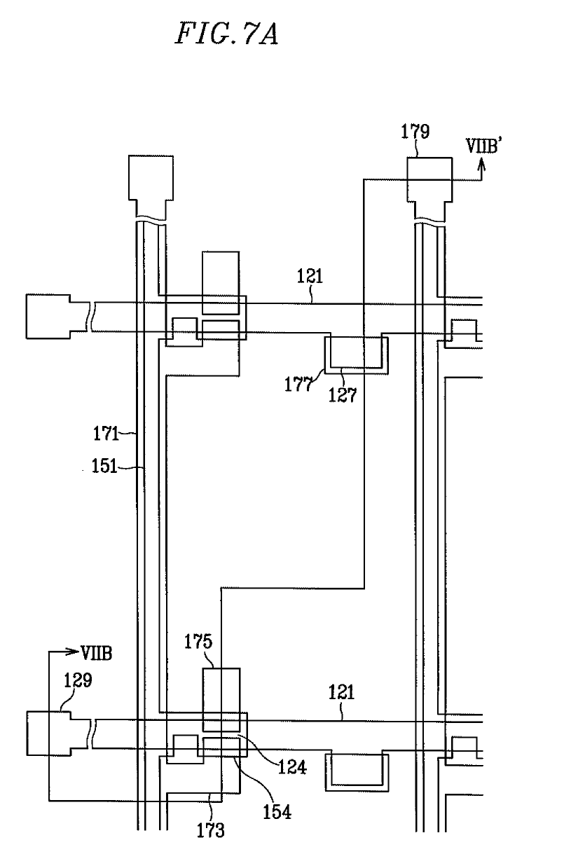

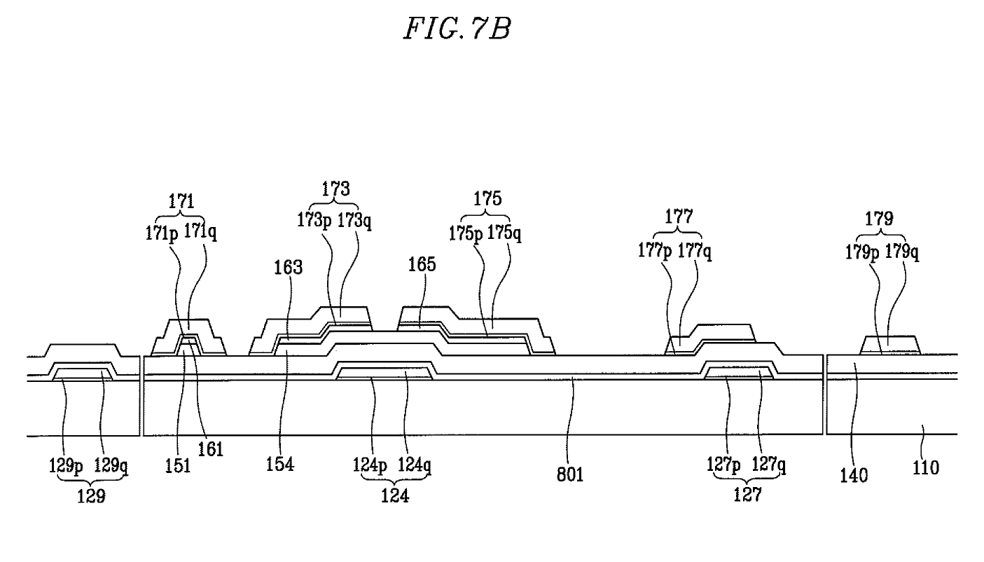

A lower layer including Mo, Cr, Ti, Ta, alloys thereof, or nitride thereof and a upper Cu layer including Cu are formed on the doped amorphous silicon layer 161 by a sputtering. Like gate lines 121, the lower layer and the upon Cu layer can be formed by co-sputtering. The detailed method for co-sputtering is like the method of co-sputtering the gate lines 121 described above referring to FIGS. 3A and 3B. The lower layer and the Cu layer is patterned to form data lines 171 (FIG. 7A) including source electrodes 173 and end portions 179, drain electrodes 175, and storage capacitor conductors 177 as shown in FIGS. 7A and 7B.

Doped amorphous silicon, which is exposed between the source electrodes 173 and the drain electrodes 175 is removed to form ohmic contact layers 164, 163 and 165 (FIG. 7B), and to expose portions of intrinsic semiconductors 154. The exposed surface of the intrinsic semiconductors 154 is stabilized in a well-known manner by an oxygen plasma treatment.

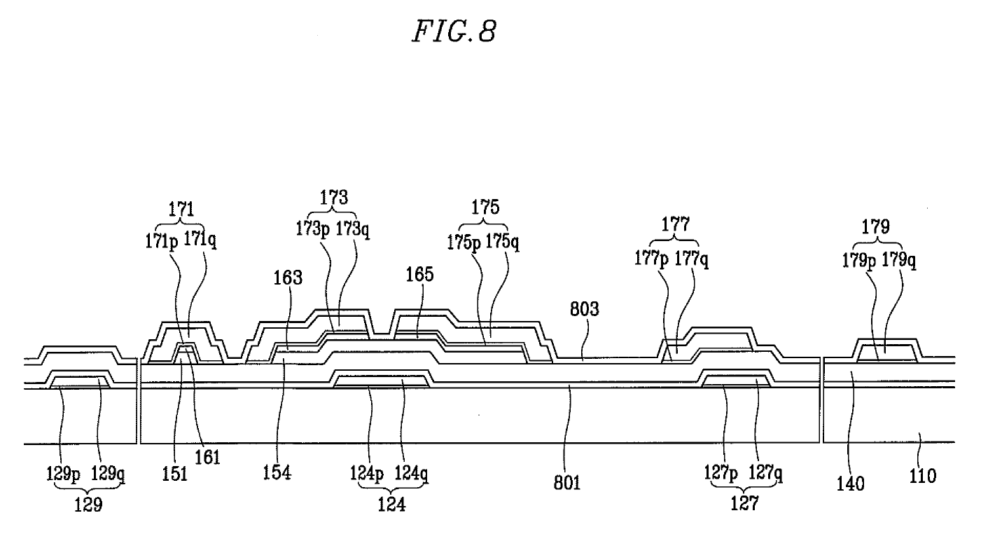

Referring to FIG. 8, a protection layer 803 is formed on-the-data lines 171 including the source electrodes 173 and the end portions 179, the drain electrodes 175, and the storage capacitor conductors 177.

The protection layer 803 is formed of a material including Si, such as SiO₂, SiON, or amorphous Si by a plasma enhanced chemical vapor deposition (PECVD).

SiO₂ can be formed by passing SiH₄ and N₂O over the data lines 171, the drain electrodes 175 and the storage capacitor conductors 177 by PECVD. At the same time, N₂ gas can be added to form SiON. The protection layer 801 formed of SiON may include more N₂ concentration in its upper portions, and may be formed of only nitride in the portion adjacent the gate insulating layer 140. For example, 9000 sccm of N₂O and 130 sccm of SiH₄ are flowed to form about 500 Å of SiO₂, and then 7000 sccm of N₂O, 500 sccm of NH₃, and 130 sccm of SiH₄ are flowed to form about 2500 Å to 3000 Å of SiON. 5000 sccm of N₂, 800 sccm of NH₃, and 130 sccm of SiH₄ are flowed to form about 500 Å of SiNx in the portion adjacent the gate insulating layer 140.

In another embodiment for forming the protection layer 803, amorphous silicon is formed on the data lines 171, the drain electrodes 175 and the storage capacitor conductors 177 by PECVD, and then amorphous silicon is annealed in about 400° C. to 800° C. by a rapid thermal annealing (RTA) to react amorphous silicon with Cu of the data lines 171, the drain electrodes 175 and the storage capacitor conductors 177 to form copper silicide. Copper-silicide can be formed only in the interface of the data lines 171, the drain electrodes 175 and the storage capacitor conductors 177, and the amorphous silicon by controlling the reaction condition.

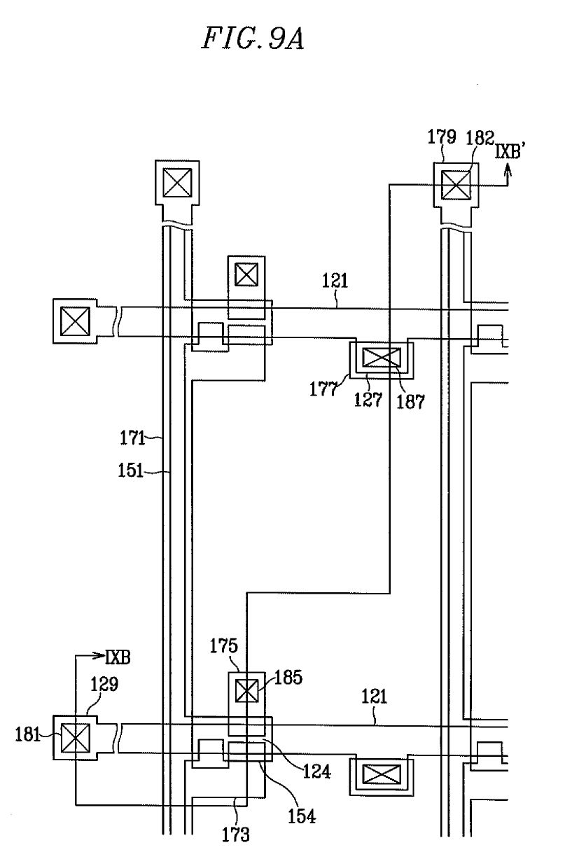

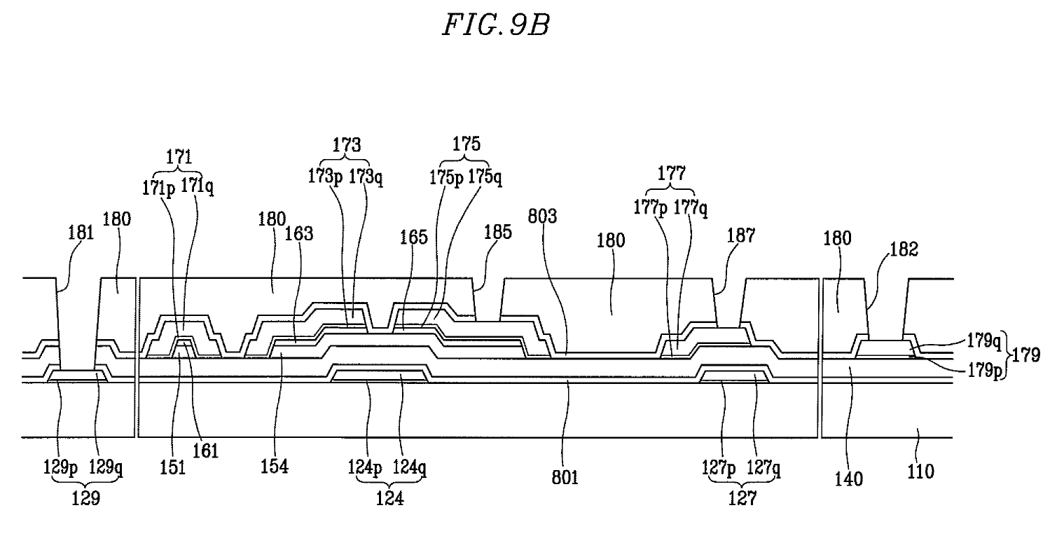

The protection layer 803 protects the Cu layer 171q, 173q, 175q, 177q, and 179q during the following process for forming a passivation layer 180 (FIG. 9B). The thickness of the protection layer 803 is about 30 Å to 300 Å.

Referring to FIGS. 9A and 9B, passivation layer 180 including SiNx is formed on the protection layer 803.

Conventionally, passivation layer 180 including SiNx can be formed by passing silane (SiH4), nitrogen (N2) and ammonium (NH3) gases at the same time over the substrate 110 having the gate lines 121. As is well known, NH3 gas corrodes many metals including Cu. Accordingly, when the copper layer 171q, 173q, 175q, 177q, and 179q is exposed to NH3 gas, copper layer 171q, 173q, 175q, 177q, and 179q oxidizes and corrodes. Oxidation and corrosion cause the resistance of the copper layer 171q, 173q, 175q, 177q, and 179q to increase, and decrease the adhesion of the copper layer 171q, 173q, 175q, 177q, and 179q with the passivation layer 180. The decrease of the adhesion allows the copper layer 171q, 173q, 175q, 177q, and 179q to separate from the adjacent material.

The protection layer 803 between the copper layer 171q, 173q, 175q, 177q, and 179q and the passivation layer 180 solves these problems.

The passivation layer 180 (FIGS. 9A and 9B) is patterned to form contact holes 181, 185, 187, and 182.

A transparent conductor, such as ITO or IZO, is formed and patterned to form pixel electrodes such as electrode 190 (FIGS. 1 and 2) and contact assistants 81 and 82.

In this embodiment, both of the protection layers 801 and 803 (FIG. 9B) are formed over the gate lines and the data lines, however, if desired, only one of protection layer can be formed over either the gate lines or the data lines.

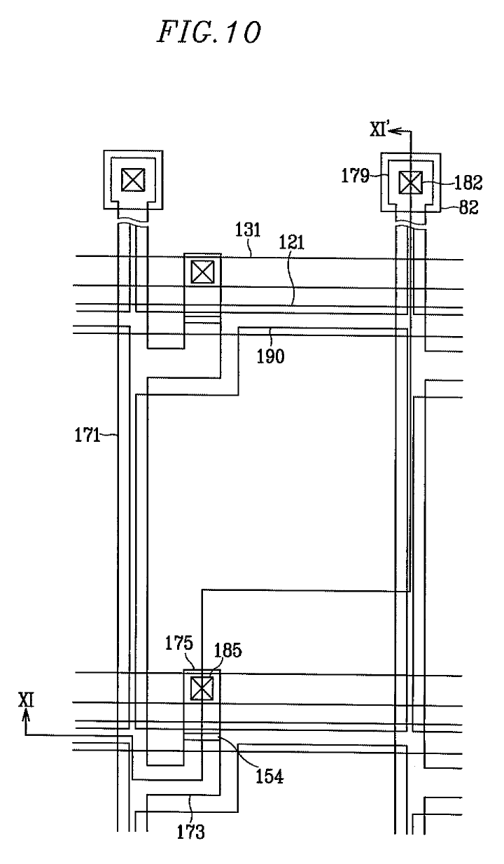

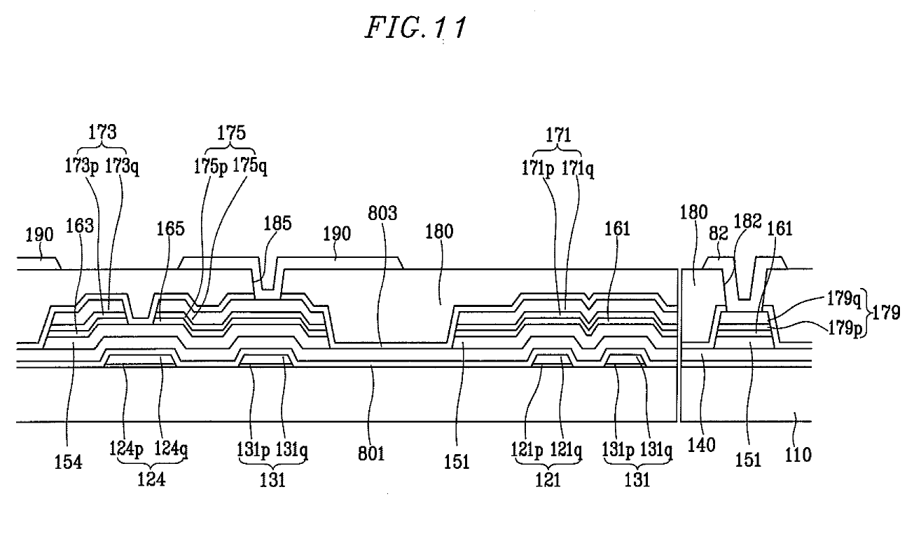

FIG. 10 is a plan view of a TFT array panel according to another embodiment of the present invention and FIG. 11 is a cross sectional view take along the line XI-XI′ of FIG. 10.

Referring to FIGS. 10 and 11, a plurality of gate lines 121 transmitting gate signals are formed on an insulating substrate 110. Gate lines 121 extend in a horizontal direction, and a portion of each gate line 121 forms a gate electrode 124. A plurality of storage electrode lines 131 are formed in parallel to the gate lines 121 and electrically separated from the gate lines. Each storage electrode line 131 overlaps a drain electrode 175 and forms a storage capacitor with a pixel electrode 190.

The gate line 121 and the storage electrode line 131 are formed of a conductive layer (i.e. copper layer) 121q, 124q and 131q including copper or a copper alloy, and a lower conductive layer 121p, 124p, and 131p in order to improve the adhesion of the copper layer 121q, 124q and 131q to the insulating substrate 110. The lower conductive layer 121q, 124q and 131q can include molybdenum (Mo), chrome (Cr), titanium (Ti), tantalum (Ta), alloys thereof, nitrides thereof, or combinations thereof.

The lower conductive layer 121p, 124p and 131p prevents the copper layer 121q, 124q, and 131q from lifting or peeling.

Copper layer 121q, 124q and 131q and lower conductive layer 121p, 124p and 131p may have tapered lateral sides having an inclination angle in the range of about 30 to 80 degrees, relative to the surface of the first substrate 110.

A protection layer 801 is formed on the gate lines 121 and the storage electrode lines 131.

Protection layer 801 prevents the copper layer 121q, 124q, and 131q forming the gate lines 121 from corroding and oxidizing.

Protection layer 801 includes silicon (Si), and can be made of silicon oxide (SiO₂), silicon oxynitride (SiON), or silicide.

The thickness of protection layer 801 is about 30 to 300 Å considering the protection of the copper layer and storage capacitance.

A silicon nitride (SiNx) gate insulating layer 140 is formed over the protection layer 801.

Conventionally, gate insulating layer 140 including SiNx can be formed by providing silane (SiH₄), nitrogen (N₂) and ammonium (NH₃)gases at the same time to the substrate 110 having the gate lines 121. NH3 gas corrodes metal. Accordingly, when the copper layer 121q, 124q, and 131q is exposed to NH3 gas, copper layer 121q, 124q, and 131q oxidizes and corrodes. Oxidation and corrosion increase the resistance of the copper layer 121q, 124q, and 131q, and decrease the adhesion between the copper layer 121q, 124q, and 131q and the gate insulating layer 140. The decreased adhesion allows the copper layer 121q, 124q, and 131q to separate from the gate insulating layer 140.

The protection layer 801 between the copper layer 121q, 124q, and 131q and the gate insulating layer 140 solves these problems.

A plurality of semiconductor strips 151 made of hydrogenated amorphous silicon is formed over the gate insulating layer 140. Each semiconductor strip 151 extends in a longitudinal direction and has a plurality of projections 154 branched out toward the gate electrode 124.

A plurality of ohmic contact strips 161 and ohmic contact islands 163 and 165 made of silicide or n+ hydrogenated amorphous silicon highly doped with n type impurity are formed on the semiconductor strips 151. A pair of island ohmic contact layers 163 and 165 is located on the projections 154 of the semiconductor strips 151.

The lateral sides of the semiconductor layer 151 and 154, and the ohmic contact layer 161, 163, and 165 are inclined at angles in the range about 40 to 80 degrees relative to the surface of the substrate 110.

A plurality of data lines 171 including source electrodes 173 and a plurality of drain electrodes 175 are formed on the ohmic contact layer 161, 163, and 165 and the gate insulating layer 140.

The data lines 171 are configured to transmit data signals and extend in the substantially longitudinal direction intersecting the gate lines 121. Each data line 171 has an end portion 179 having a relatively large area for contact with other layers or external devices. The data lines 171 may include a plurality of branches that project toward the drain electrodes 175. These branches form source electrodes 173. Each pair of the source electrode 173 and the drain electrode 175 are located at least in part on the relevant ohmic contacts 163 and 165, and separated from and opposite each other with respect to the gate electrodes 124.

The data lines 171 including the source electrode 173, and the drain electrodes 175 can be formed of double layers. Upper layers 171q, 173q, 175q, 177q, and 179q include Cu. Lower layers 171p, 173p, 175p, 177p, and 179p include Mo, Cr, Ti, Ta, alloys thereof, nitrides thereof, or combinations thereof, to prevent Cu from entering into the semiconductor layers 151 and 154, and the ohmic contact layers 161 and 164.

In another embodiment, the data lines 171 and the drain electrodes 175 can be formed of Cu single layer or multi-layer not less than triple layer.

Like the gate lines 121, the data lines 171 and the drain electrodes 175 may have tapered lateral sides having an inclination angle in the range of about 30 to 80 degrees, relative to the surface of the first substrate 110.

The gate electrode 124, the source electrode 173, the drain electrode 175 and the projection 154 of the semiconductor strip 151 together forms a TFT. A TFT channel (not shown) is formed on the projection 154 between the source electrode 173 and the drain electrode 175.

A protection layer 803 is formed on the data lines 171, the drain electrodes 175, and the exposed semiconductor layers 154.

The protection layer 803 prevents the copper layer 171q, 173q, 175q, 177q, and 179q from oxidation and corrosion during the following process steps.

The protection layer 803 is formed of material including silicon (Si), such as silicon oxide (SiO₂), silicon oxynitride (SiON), or silicide.

The thickness of the protection layer 803 is about 30 to 300 Å.

A passivation layer 180 made of silicon nitride (SiNx) is formed on the protection layer 803.

Conventionally, the passivation layer 180 including SiNx can be formed by passing silane (SiH₄), nitrogen (N₂) and ammonium (NH₃) gases at the same time over the substrate 110. NH3 gas corrodes metal. Accordingly, when the copper layer 171q, 173q, 175q, and 179a is exposed to NH3 gas, copper layer 171q, 173q, 175q, and 179a oxidizes and corrodes. Oxidation and corrosion cause the electrical resistance of the copper layer 171q, 173q, 175q, and 179q to increase, and the adhesion of the copper layer 171q, 173q, 175q, and 179a with different layer to decrease. The decrease of the adhesion allows the passivation layer 180 to separate from the underlying structure.

The protection layer 803 between the copper layer 171q, 173q, 175q, and 179q and the passivation layer 180 solves these problems.

The passivation layer 180 includes a plurality of contact holes 182 and 185 to expose the ending portion 179 of the data line 171 and a portion of the drain electrode 175 respectively.

A plurality of pixel electrodes 190 made of indium tin oxide (ITO) or indium zinc oxide (IZO), and contact assistants 82 are formed on the passivation layer 180.

Each pixel electrode 190 is connected electrically to the drain electrode 175 through the contact hole 185 to receive a data voltage.

Each pixel electrode 190 provided with a data voltage and the other panel having a common electrode provided with a common voltage (not shown) generate an electric field in an LC layer (not shown) disposed between the pixel electrode 190 and the common electrode to orient LC molecules.

The contact assistants 82 are connected to the end portions 179 of the data lines 171 through the contact holes 182. The contact assistants 82 protect the end portions 179 of the data lines 171 and enhance adhesion of the end portions 179 to external devices.

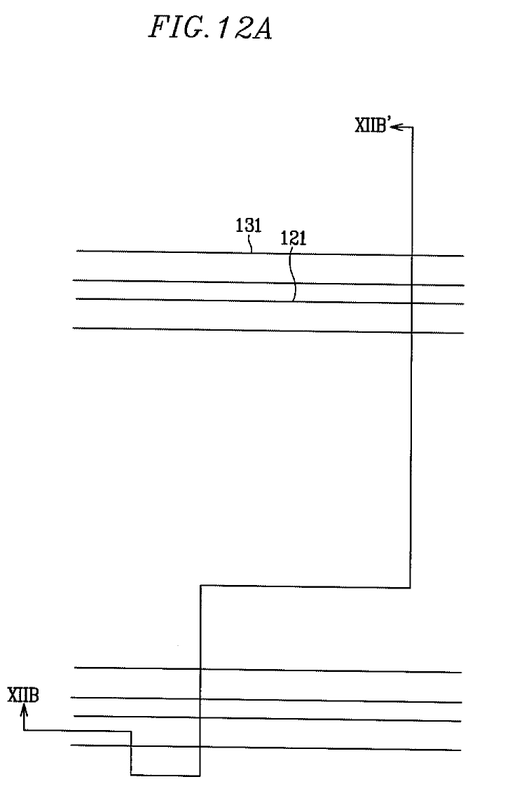

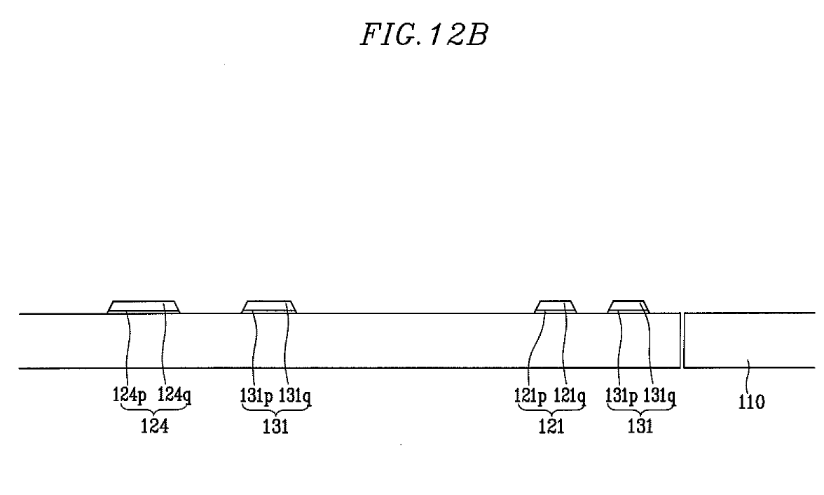

Hereinafter, a method for fabricating the TFT array panel of FIGS. 10 and 11 will be described in detail referring to FIGS. 12A to 19B.

Referring to FIGS. 12A and 12B, a lower layer 121p, 124p, and 131p including Mo, Cr, Ti, Ta, alloys thereof, nitrides thereof, or combinations thereof, and a upper layer 121q, 124q, and 131q including Cu or Cu alloy (i.e Cu layer) are formed on a substrate 110 by co-sputtering.

In one embodiment, both a Cu target and a Mo target are located in a chamber for co-sputtering. In the beginning, electric power is applied to only the Mo target so that the lower layer 121p, 124p, and 131p made of Mo is formed on the substrate 110. N2 gas can be provided to form molybdenum nitride during the Mo sputtering. In this case, nitride can be formed between the lower layer of molybdenum and the to-be-formed Cu layer, to prevent Cu from diffusing into the lower layer. The thickness of the lower layer is about 30 Å to 300 Å.

After the electric power applied to the Mo target is turned off, electric power is applied to only the Cu target to form Cu layers 121q, 124q, and 131q. The thickness of the Cu layers is about 1000 to 3000 Å.

The Cu layers 121q, 124q, and 131q are formed in a well-known manner by depositing (e.g. sputtering) Cu onto molybdenum which in turn has been sputtered onto substrate 110, and then patterning the copper and molybdenum to form the gate lines 121 including the gate electrodes 124, and the storage electrode lines 131 as shown in FIGS. 12A and 12B.

The lower layer 121p, 124p, and 131p made of a material such as Mo, under the Cu layer increases the adhesion of the Cu layer with the substrate 110 to prevent the Cu layer from peeling or lifting, and prevents oxidized Cu from diffusing the substrate 110.

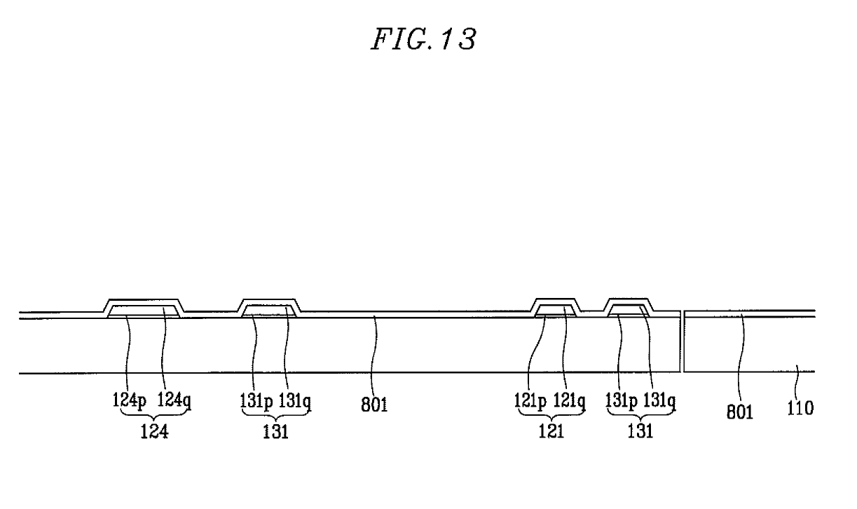

Referring to FIG. 13, a protection layer 801, formed of a material including Si, such as SiO₂, SiON, or amorphous Si by a plasma enhanced chemical vapor deposition (PECVD), is formed on the gate lines 121 and the storage electrode line 131.

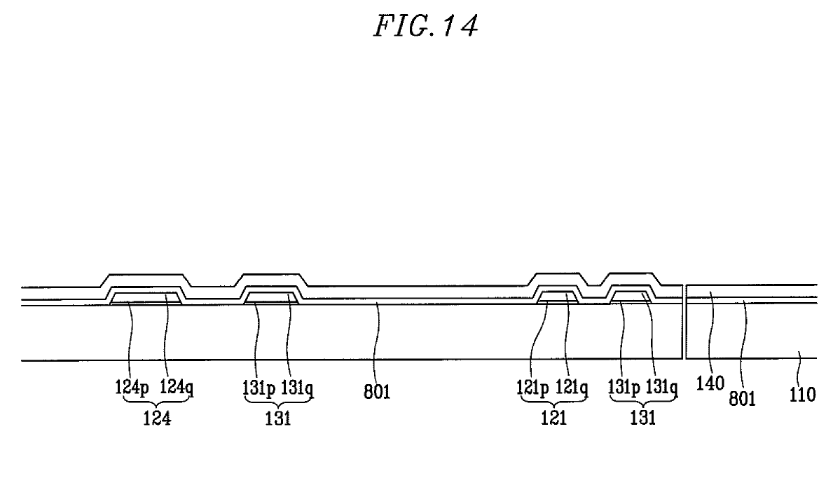

SiO₂ can be formed by providing SiH₄ and N₂O to the gate lines 121 by PECVD. At the same time, N₂ gas can be added to form SiON. The protection layer 801 formed of SiON may include more N₂ concentration in the upper protection layer, and may be formed of only nitride in the top portion of protection layer 801 directly beneath to-be-formed the gate insulating layer 140 (FIG. 14).

In another embodiment to form the protection layer 801, amorphous silicon is formed on the gate lines 121 and the storage electrode line 131 by PECVD, and then amorphous silicon is annealed in about 400 to 800° C. by a rapid thermal annealing (RTA) to react amorphous silicon with Cu of the gate lines 121 and the storage electrode lines 131 to form copper silicide. Copper silicide can be formed in the only interface of the gate line 121 and the storage electrode line 131, and the amorphous silicon by controlling the reaction condition.

The protection layer 801 protects the copper layer 121q, 124q, and 131q during the following process for forming a gate insulating layer 140. The thickness of the protection layer 801 is about 30 Å to 300 Å. When the thickness of the protection layer 801 is less than 30 Å, the protection layer 801 can not protect the Cu layer 121q, 124q, and 131q. When the thickness of the protection layer 801 is larger than 300 Å, the capacitance of a storage capacitor using a portion of protection layer 801 as the capacitor's dielectric decreases.

Referring to FIG. 14, the gate insulating layer 140 including SiNx is formed on the protection layer 801 and in the range of about 250 to 500° C. The thickness of the gate insulating layer 140 is about 2,000 Å to 5,000 Å.

Conventionally, gate insulating layer 140, which may include SiNx, can be formed by passing silane (SiH₄), nitrogen (N₂) and ammonium (NH₃) gases at the same time over the substrate 110. NH3 corrodes metal. Accordingly, when the Cu layer 121q, 124q, and 131q is exposed to NH3 gas, Cu layer 121q, 124q, and 131q oxidizes and corrodes. Oxidation and corrosion cause the resistance of the Cu layer 121q, 124q, and 131q to increase, and decrease the adhesion of the Cu layer 121q, 124q, and 131q to the gate insulating layer 140. This decrease of the adhesion allows the copper layer 121q, 124q, and 131q to separate from the gate insulating layer 140

The protection layer 801 between the copper layer 124q, 127q, and 129q and the gate insulating layer 140 solves these problems.

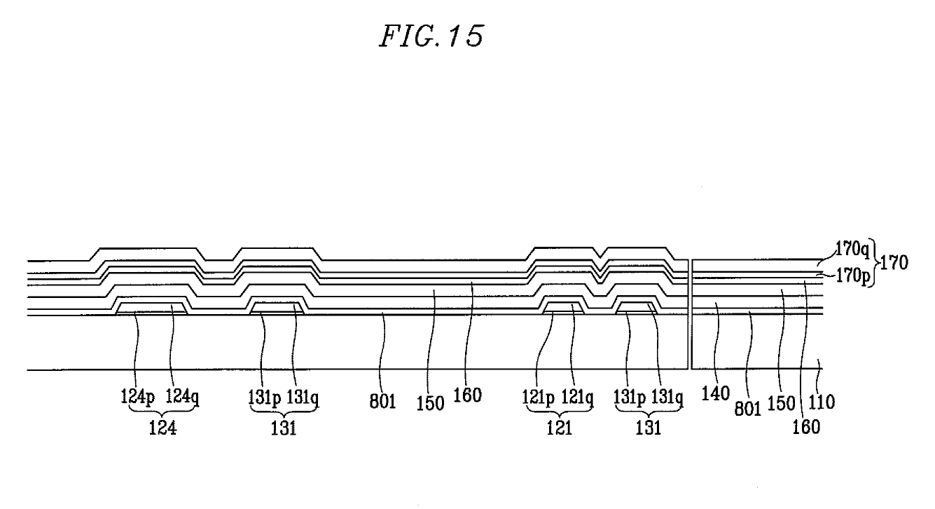

Referring to FIG. 15, an intrinsic amorphous silicon layer 150 made of hydrogenated amorphous silicon (a-Si:H) and an extrinsic amorphous silicon layer 160 doped highly with n type impurities, such as phosphorus are formed on the gate insulating layer 140.

A lower conductive layer 170p including Mo, Cr, Ti, Ta, alloys thereof, or nitride thereof and a upper Cu layer 170q including Cu are formed on the doped amorphous silicon layer 160 by sputtering.

Like gate lines 121, the lower layer and the Cu layers can be formed by a co-sputtering as described above.

In one embodiment, both a Cu target and a Mo target are located in a chamber for co-sputtering. In the beginning, electric power is applied to only the Mo target so that the lower conductive layer 170p made of Mo is formed on the substrate 110. N2 gas can be provided to form molybdenum nitride during the Mo sputtering. In this case, molybdenum nitride formed between the lower conductive layer 170p and the Cu layer 170q, prevents Cu from diffusing into the lower molybdenum conductive layer 170p. The thickness of the lower layer is about 30 Å to 300 Å.

After the electric power applied to the Mo target turns off, electric power is applied to only Cu target to form the Cu layer 170q. The thickness of the Cu layer 170q is about 1000 Å to 3000 Å.

The lower conductive layer 170p made of a material such as Mo, under the Cu layer 170q increases the adhesion of the Cu layer 170q to the substrate 110 to prevent the Cu layer 170q from peeling or lifting, and prevents oxidized Cu from diffusing into the substrate 110.

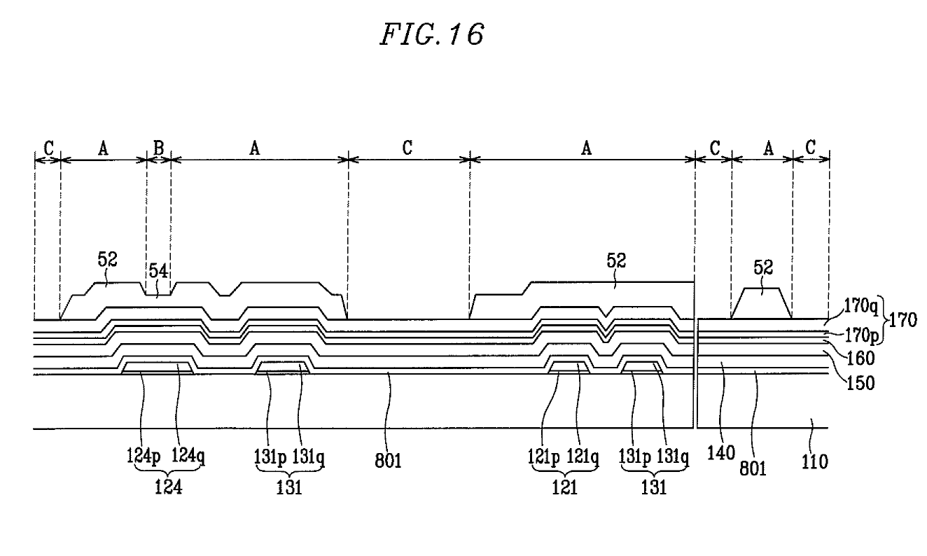

A photoresist film is coated on the Cu layer 170q. The photo-resist film is exposed to light through an exposure mask, and developed to form a photo-resist pattern including a plurality of first and second portions 52 and 54 having different thicknesses as shown in FIG. 16, and provided as described below.

Each of the second portions 54, which is placed over a channel area B of a TFT, has a thickness smaller than the thickness of the first portions 52 placed on data line areas A. The portions of the photoresist film on the remaining areas C are removed or have a very small thickness. The thickness ratio of the second portions 54 on the channel areas B to the first portions 52 on the data areas A is adjusted depending upon the etching conditions in the subsequent etching steps. It is preferable that the thickness of the second portions 54 is equal to or less than half of the thickness of the first portions 52.

The position-dependent thickness of the photoresist film is obtained by several techniques, such as, for example, providing semi-transparent areas as well as transparent areas and opaque areas on the exposure mask. The semi-transparent areas alternatively have a slit pattern, a lattice pattern, a thin film(s) with intermediate transmittance or intermediate thickness. When using a slit pattern, it is preferable that the width of the slits or the distance between the slits is smaller than the resolution of a light exposer used for the photolithography. Another example is to use reflowable photoresist. That is, once a photoresist pattern made of a reflowable material is formed by using a normal exposure mask having only transparent areas and opaque areas, the photoresist pattern is subject to a reflow process to flow onto areas without the photoresist, thereby forming thin portions.

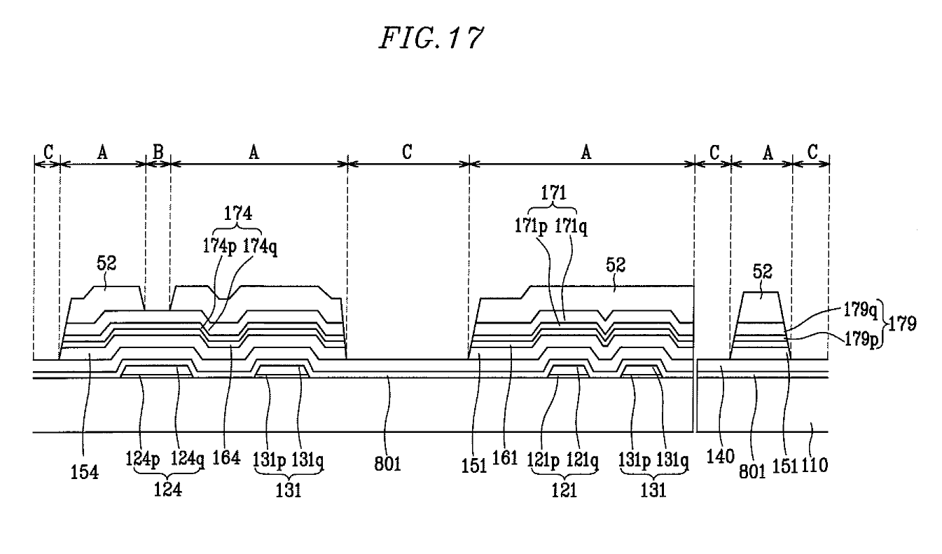

Referring to FIG. 17, the exposed portions of the lower conductive layer 170p and the Cu layer 170q in the areas C are removed to expose the underlying portions of the doped amorphous silicon layer 160 (FIG. 16).

Sequentially, the exposed portions of the doped amorphous silicon layer 160 in the areas C and the underlying portions of the semiconductor layer 150 are removed to expose the underlying gate insulating layer 140. The second portions 54 of the photoresist pattern in the area B are removed either simultaneously with or independent from the removal of the doped amorphous silicon layer 160 and the semiconductor layer 150 to expose the Cu layer 174q. Residue of the second portions 54 remaining on the channel area B is removed by ashing.

The conductor 174 including the Cu layer 174q and the lower conductive layer 174p, and the amorphous silicon 164 doped with impurities in the area B placed on the channel of a TFT are removed.

During the removal of the conductor 174, and the amorphous silicon 164 doped with impurities, a portion of intrinsic amorphous silicon 154 can be removed to cause the thickness reduction. The first portion 52 of the photo-resist pattern in the area A is now removed to complete the removal of all photoresist.

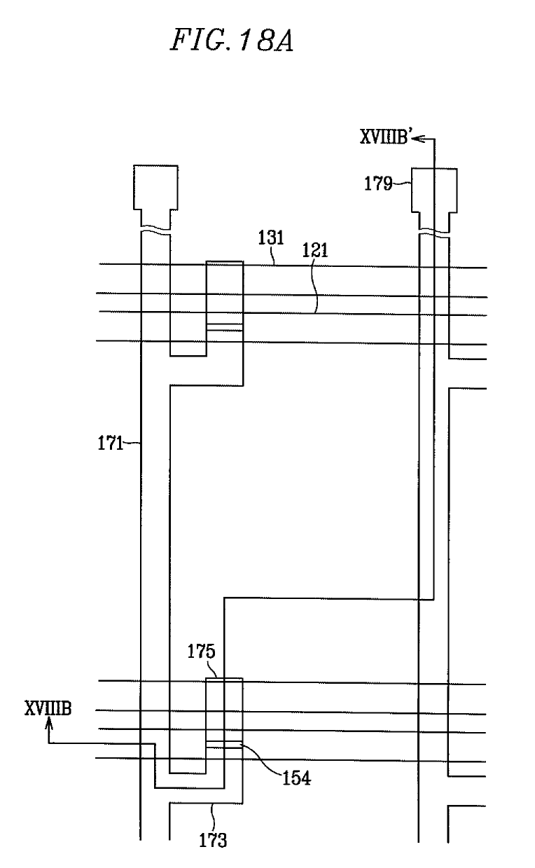

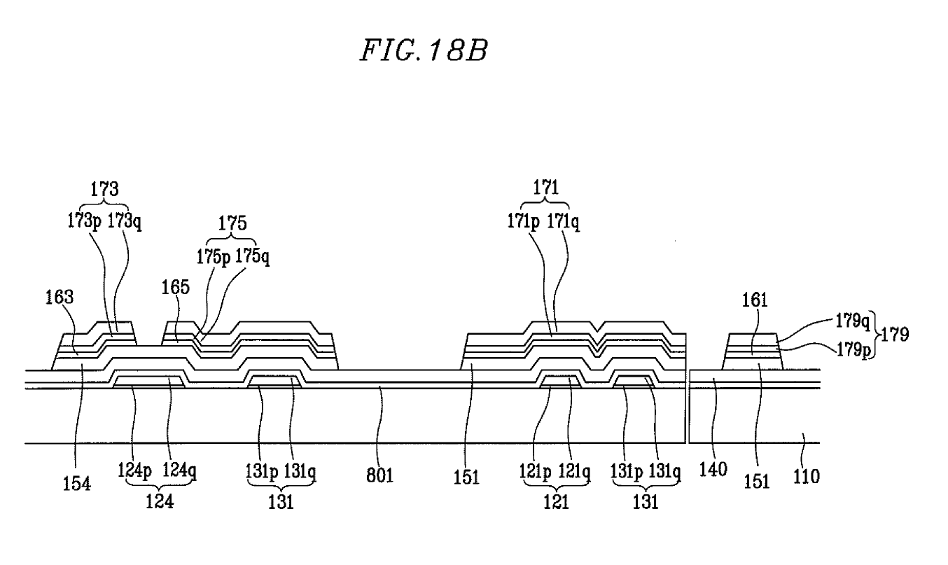

Referring to FIGS. 18A and 18B, in this way, each conductor 174 (FIG. 17) on the channel area B is divided into a data line 171 having source electrodes 173 and drain electrodes 175. Also, each doped amorphous silicon strip 164 is divided into an ohmic contact strip 161 and a plurality of ohmic contact islands 165.

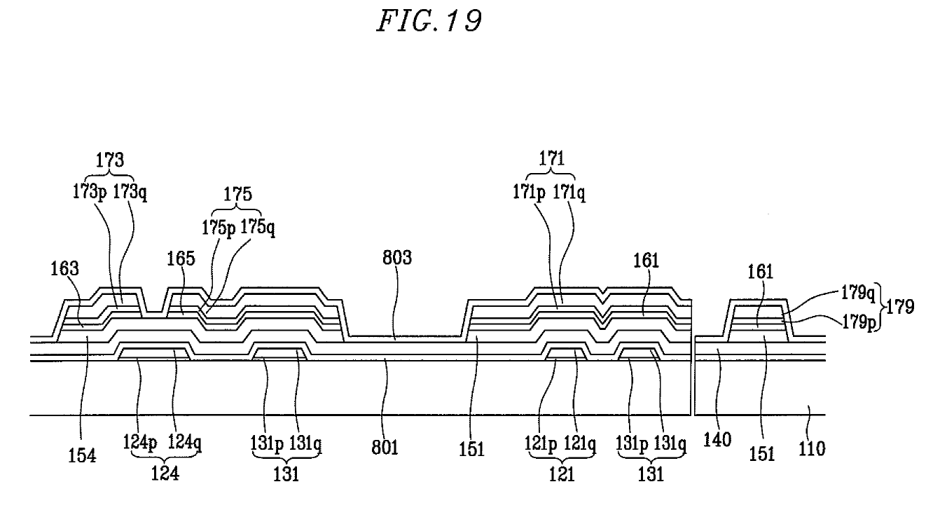

Referring to FIG. 19, a protection layer 803 is formed on the data lines 171 including source electrodes 173 and the end portions 179, and the drain electrodes 175.

The protection layer 803 is formed of a material including Si, such as SiO₂, SiON, or amorphous silicon by plasma enhanced chemical vapor deposition (PECVD).

SiO₂ can be formed by passing SiH₄ and N₂O over the data lines 171 and the drain electrodes 175 by PECVD. At the same time, N₂ gas can be added to form SiON. The protection layer 803 formed of SiON may include more N₂ concentration in the upper portion of the protection layer 803, and may be formed of only nitride in the top portion just below passivation layer 180.

In another embodiment, an amorphous silicon layer is formed on the data lines 171 to form the protection layer 803 and then the drain electrodes 175 by PECVD, amorphous silicon is annealed at about 400° C. to 800° C. by rapid thermal annealing (RTA) to react amorphous silicon with Cu of the data lines 171 and the drain electrodes 175 to form copper silicide. Copper silicide can be formed only in the interface of the data lines 171 and the drain electrodes 175, and the amorphous silicon by controlling the reaction condition.

The protection layer 803 protects the Cu layer 171q, 173q, 175q, and 179q during the formation of passivation layer 180. The thickness of the protection layer 803 is about 30 Å to 300 Å.

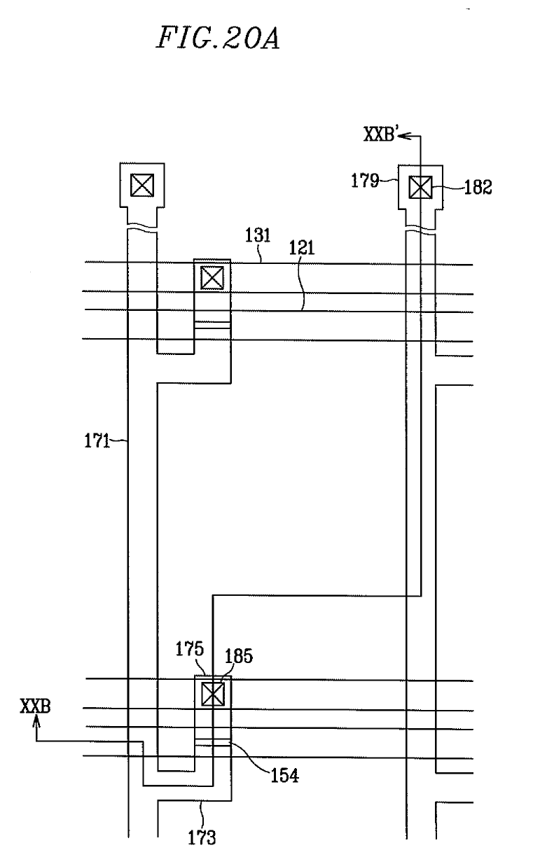

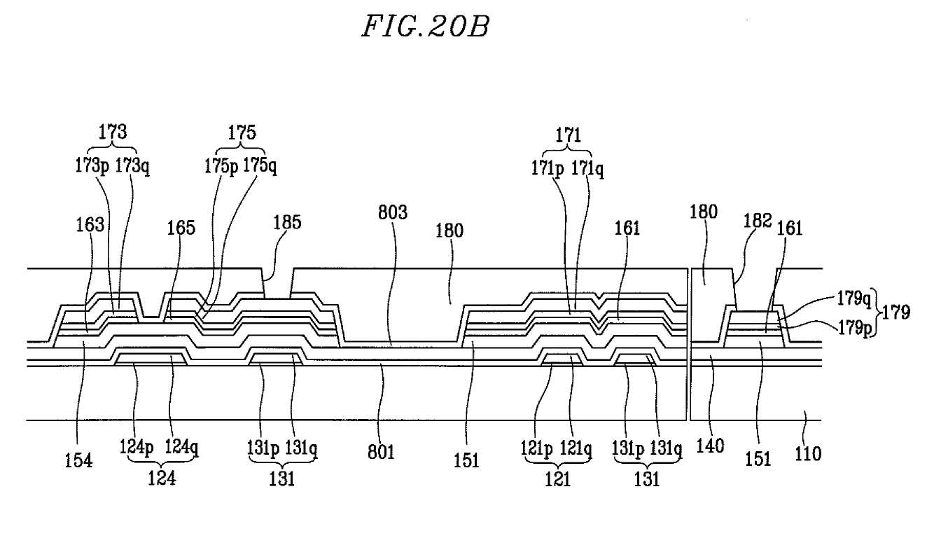

Referring to FIGS. 20A and 20B, a passivation layer 180 including SiNx is formed on the protection layer 803.

Conventionally, passivation layer 180 including SiNx can be formed by passing silane (SiH₄), nitrogen (N₂) and ammonium (NH₃) gases at the same time over the substrate 110 having the gate lines 121. NH₃ gas has a characteristic of corroding metal. Accordingly, when the Cu layer 171q, 173q, 175q, and 179q is exposed to NH₃ gas, the Cu layer 171q, 173q, 175q, and 179q oxidizes and corrodes. Oxidation and corrosion increase the resistance of the Cu layer 171q, 173q, 175q, and 179q, and decrease the adhesion of the Cu layer 171q, 173q, 175q, and 179q to the passivation layer 180. The decrease of the adhesion allows the Cu layer 171q, 173q, 175q, and 179q to separate from passivation layer 180.

The protection layer 803 between the copper layer 171q, 173q, 175q, and 179q and the passivation layer 180 solves these problems.

The passivation layer 180 is patterned to form contact holes 185 and 182.

A transparent conductor, such as ITO or IZO, is formed and patterned to form pixel electrodes 190 and contact assistants 82 as shown in FIGS. 10 and 11.

In this embodiment, both of the protection layers 801 and 803 are formed over the gate lines and the data lines, however, only one of protection layer can be formed over either the gate lines or the data lines.

A TFT array panel according to this present invention includes the protection layer such as 801 and/or 803 between the gate lines and/or the data lines, and the upper insulating layer. The protection layer prevents NH₃ gas emitted during the process forming the upper insulating layer from oxidizing and corroding Cu in the gate lines and/or the data lines, and the resistance of the gate and/or data line from increasing. Consequently, the low resistance of the wire line is secured, and the reliability of a display device having the TFT array panel, such as a LCD, OLED improves.

Although the invention has been described with reference to particular embodiments, the description is an example of the invention's application and should not be taken as a limitation. Various adaptations and combinations of the features of the embodiments disclosed are within the scope of the invention as defined by the following claims.

What is claimed is:

1. A method of manufacturing a TFT array panel comprising:
forming a gate line including a gate electrode over a substrate;
forming a gate insulating layer over the gate line;
forming a semiconductor layer over the gate insulating layer;
forming a data line including a source electrode and a drain electrode spaced apart from the source electrode over the gate insulating layer and the semiconductor layer;
forming a passivation layer on the data line and the drain electrode; and
forming a pixel electrode connected to the drain electrode,
wherein a protection layer including Si is formed before at least one of forming the gate insulating layer and forming the passivation layer.

2. The method of claim 1, wherein the protection layer is formed of SiO2.

3. The method of claim 1, wherein the protection layer is formed of SiON.

4. The method of claim 1, wherein the protection layer is formed by forming an amorphous silicon layer and annealing the amorphous silicon layer.

5. The method claim 4, wherein the amorphous silicon layer is annealed in about 400° C. to 800° C.

6. The method of claim 1, wherein the thickness of the protection layer is about 30 Å to 300 Å.

7. The method of claim 1, wherein at least one of the gate line and the data line includes Cu or Cu alloy.

8. The method of claim 1, wherein at least one of the gate line and the data line is formed by forming sequentially a first conductive layer and a second conductive layer including Cu.

9. The method of claim 8, wherein the first conductive layer includes at least one of Mo, Cr, Ti, Ta, alloys thereof, and nitrides thereof.
